(19) United States
(12) Patent Application Publication
(10) Pub. No.: US 2026/0231508 A1
(43) Pub. Date: Aug. 6, 2026

(54) SEMICONDUCTOR STRUCTURE AND MANUFACTURING METHOD THEREOF

(71) Applicant: Winbond Electronics Corp., Taichung City (TW)

(72) Inventors: Yi-Hsun Chung, Tainan City (TW); Yu-Ting Chen, Kaohsiung (TW); Kai Jen, Kaohsiung (TW)

(73) Assignee: Winbond Electronics Corp., Taichung City (TW)

(21) Appl. No.: 19/452,876

(22) Filed: Jan. 20, 2026

(30) Foreign Application Priority Data
Feb. 6, 2025 (TW) 114104323

(51) Int. Cl. H10D 64/68; H10D 30/01; H10W 20/41; H10W 80/00; H10W 90/26

(52) U.S. Cl. CPC H10D 64/691; H10D 30/027; H10W 20/435; H10W 80/327; H10W 90/26

(57) ABSTRACT

A semiconductor structure including a substrate structure and first device layers is provided. The first device layers are stacked on the substrate structure. The first device layers include semiconductor devices. Each of the semiconductor devices includes an active layer, a gate, a gate dielectric layer, a first doped region, and a second doped region. The gate is located on the active layer. The gate dielectric layer is located between the gate and the active layer. There is an air gap on one side of the gate dielectric layer. The air gap is located between the gate and the active layer. The first doped region and the second doped region are located in the active layer on two sides of the gate.

### CROSS-REFERENCE TO RELATED APPLICATION

This application claims the priority benefit of Taiwan application serial no. 114104323, filed on February 6, 2025. The entirety of the above-mentioned patent application is hereby incorporated by reference herein and made a part of this specification.

### BACKGROUND

### TECHNICAL FIELD

The invention relates to a semiconductor structure and a manufacturing method thereof, and particularly relates to a semiconductor structure having an air gap and a manufacturing method thereof.

### DESCRIPTION OF RELATED ART

The semiconductor device is widely used in the electronic product. However, as the size of the semiconductor device continues to shrink, how to further increase the device density of the semiconductor device is the goal of continuous efforts.

### SUMMARY

The invention provides a semiconductor structure and a manufacturing method thereof, which can effectively improve the device density of the semiconductor device.

The invention provides a semiconductor structure, which includes a substrate structure and first device layers. The first device layers are stacked on the substrate structure. The first device layers include semiconductor devices. Each of the semiconductor devices includes an active layer, a gate, a gate dielectric layer, a first doped region, a second doped region, a first dielectric layer, a second dielectric layer, and a third dielectric layer. The gate is located on the active layer. The gate dielectric layer is located between the gate and the active layer. There is an air gap on one side of the gate dielectric layer. The air gap is located between the gate and the active layer. The first doped region and the second doped region are located in the active layer on two sides of the gate. The first dielectric layer and the second dielectric layer are located on opposite sides of the active layer. The third dielectric layer is located between the second dielectric layer and the first doped region and between the second dielectric layer and the second doped region. The third dielectric layer seals the air gap.

The invention provides a manufacturing method of a semiconductor structure, which includes the following steps. A substrate structure is provided. First device layers are formed on the substrate structure. The first device layers are stacked on the substrate structure. The first device layers include semiconductor devices. Each of the semiconductor devices includes an active layer, a gate, a gate dielectric layer, a first doped region, a second doped region, a first dielectric layer, a second dielectric layer, and a third dielectric layer. The gate is located on the active layer. The gate dielectric layer is located between the gate and the active layer. There is an air gap on one side of the gate dielectric layer. The air gap is located between the gate and the active layer. The first doped region and the second doped region are located in the active layer on two sides of the gate. The first dielectric layer and the second dielectric layer are located on opposite sides of the active layer. The third dielectric layer is located between the second dielectric layer and the first doped region and between the second dielectric layer and the second doped region. The third dielectric layer seals the air gap.

Based on the above description, in the semiconductor structure and the manufacturing method thereof according to the invention, since the first device layers are stacked on the substrate structure, the device density of the semiconductor device can be effectively improved. In addition, when the semiconductor device is a one-transistor dynamic random access memory (1T-DRAM) device, since there is the air gap on one side of the gate dielectric layer, and the air gap is located between the gate and the active layer, the memory judgment window of the memory device can be improved.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to FIG. 1O are figures of a manufacturing process of a semiconductor structure according to some embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the perspective view and the features in the cross-sectional view are not drawn to the same scale. In fact, the dimensions of the various features may be arbitrarily increased or reduced for clarity of discussion.

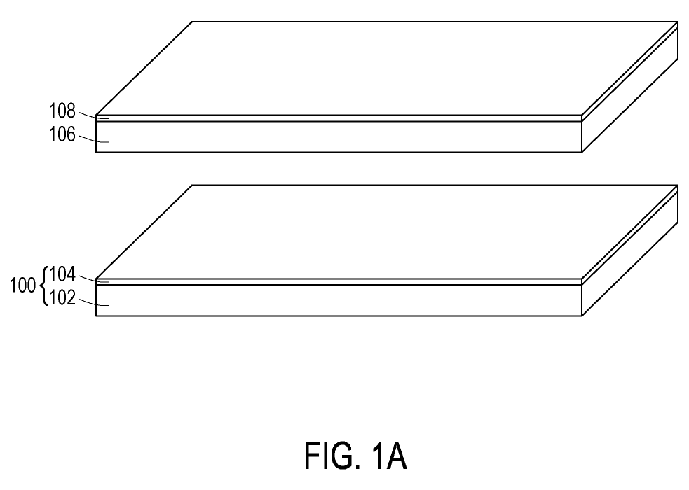

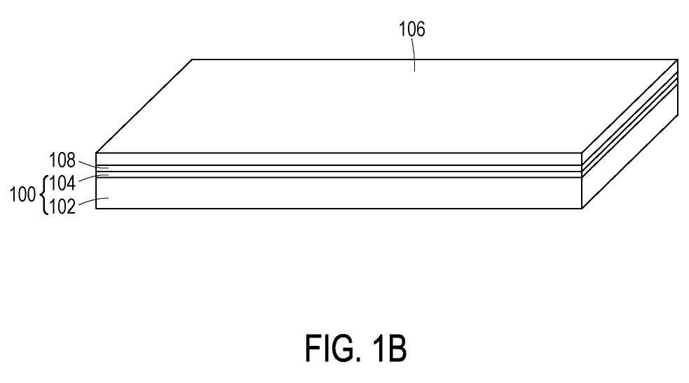

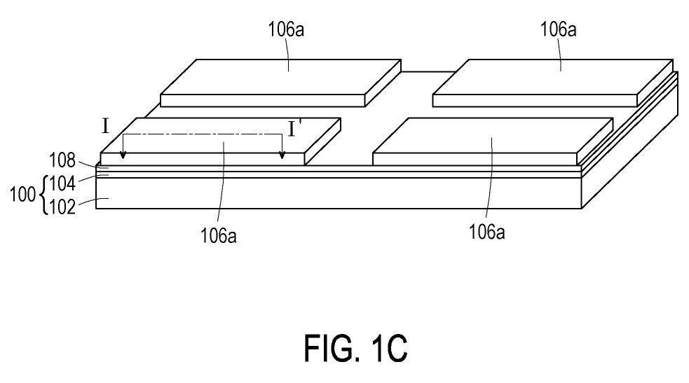

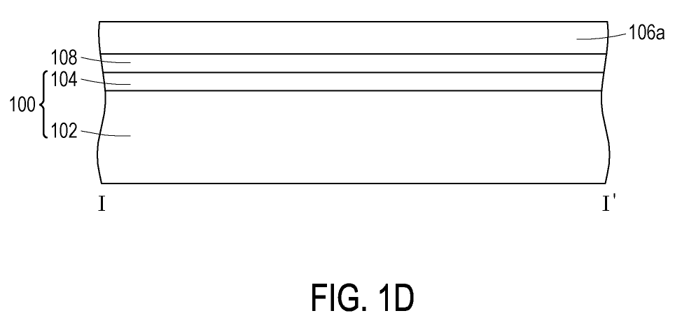

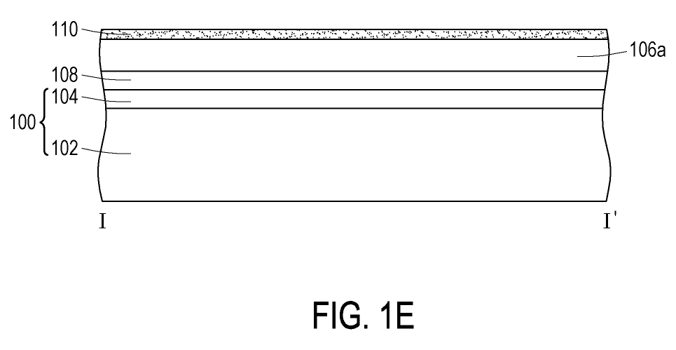

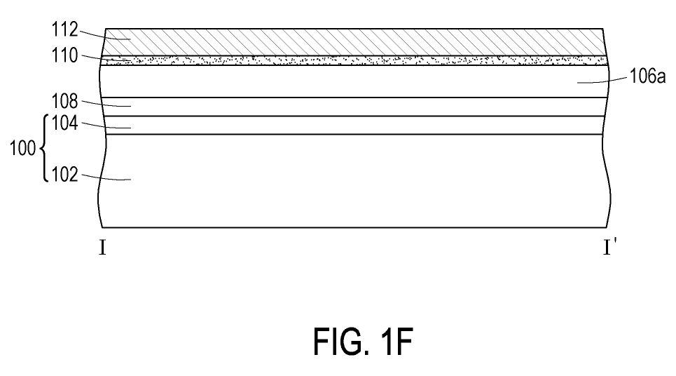

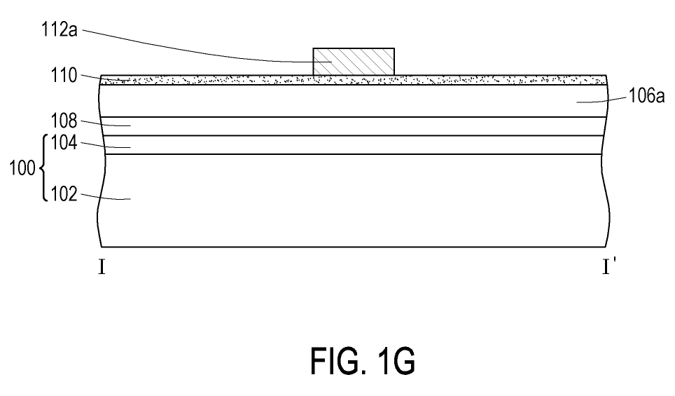

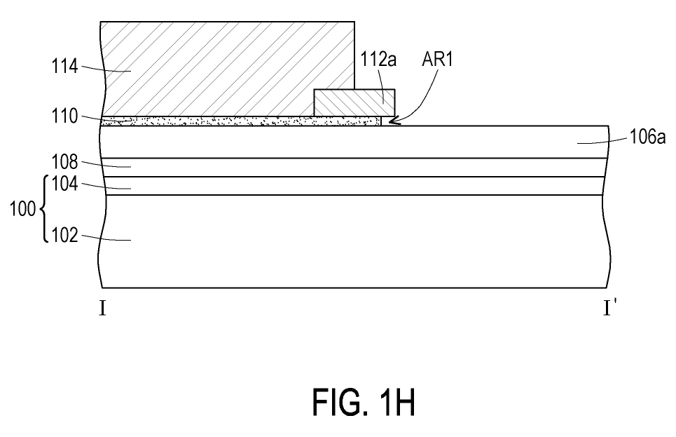

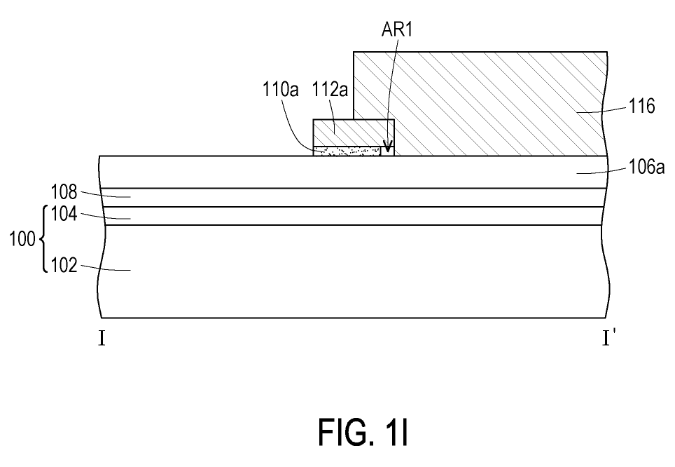

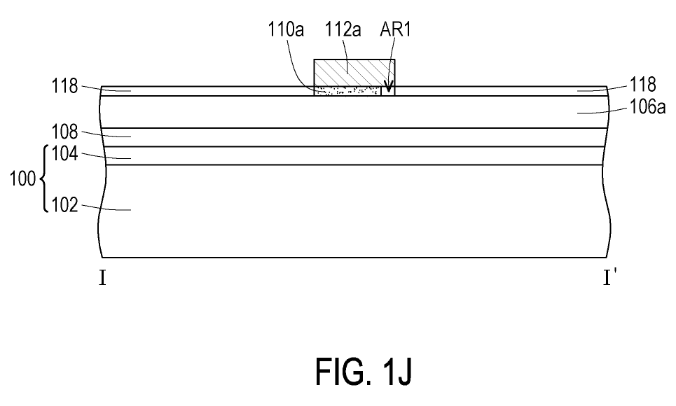

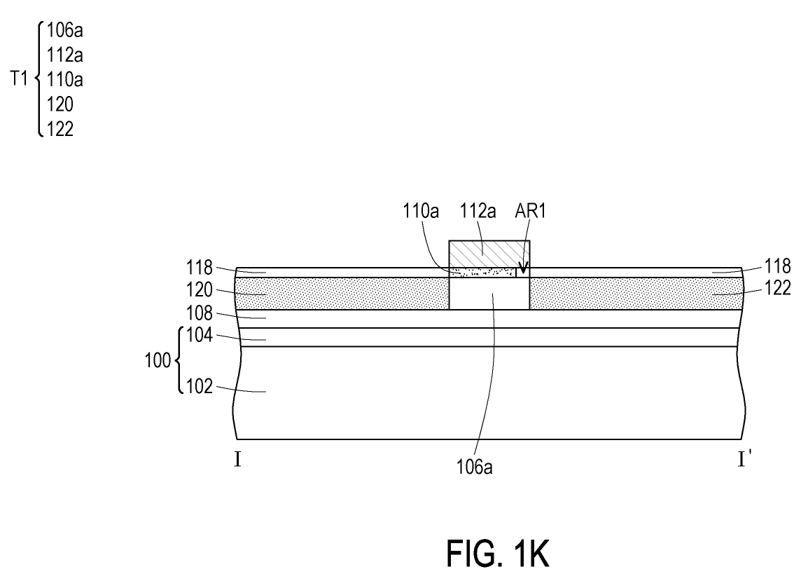

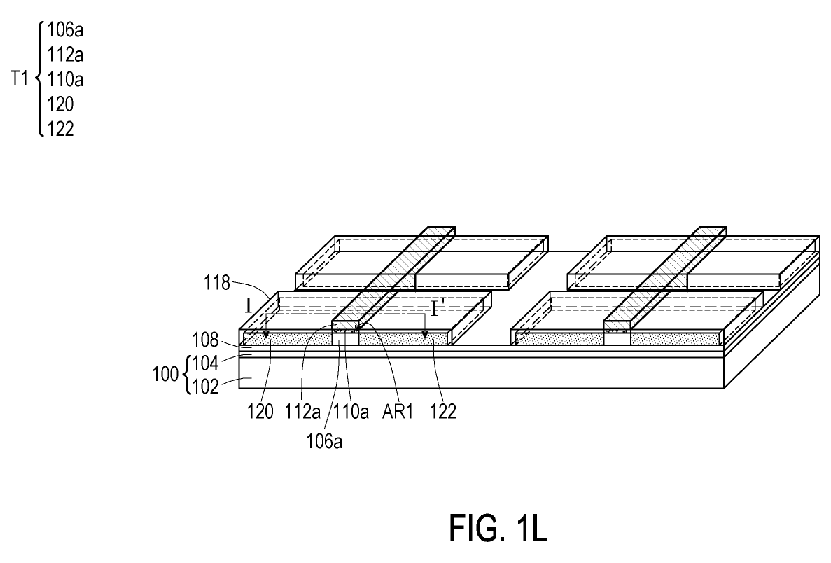

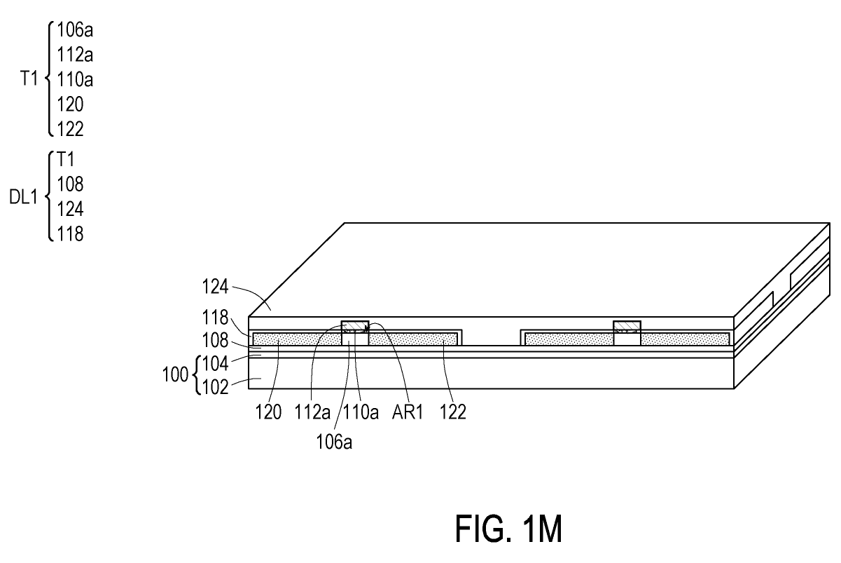

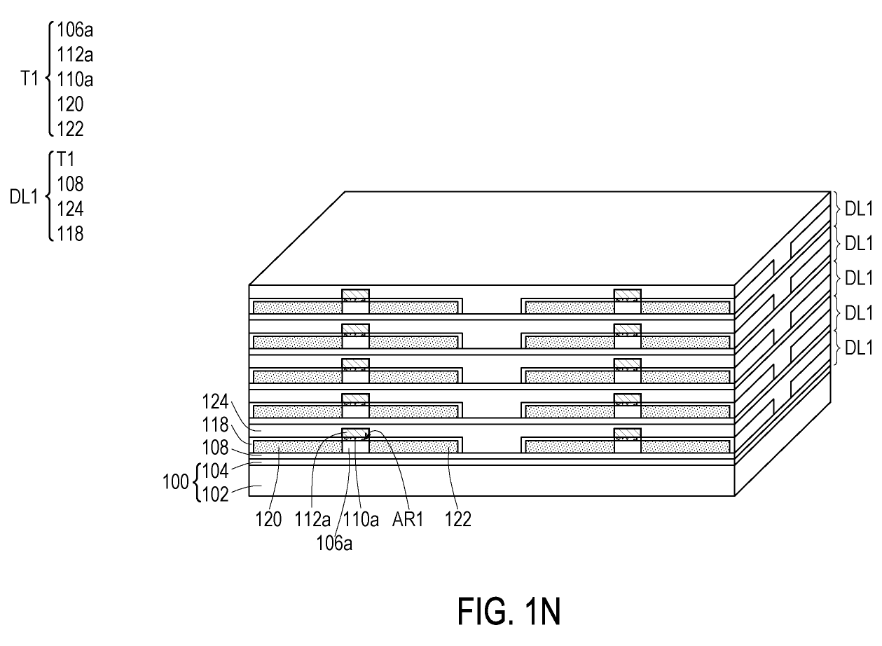

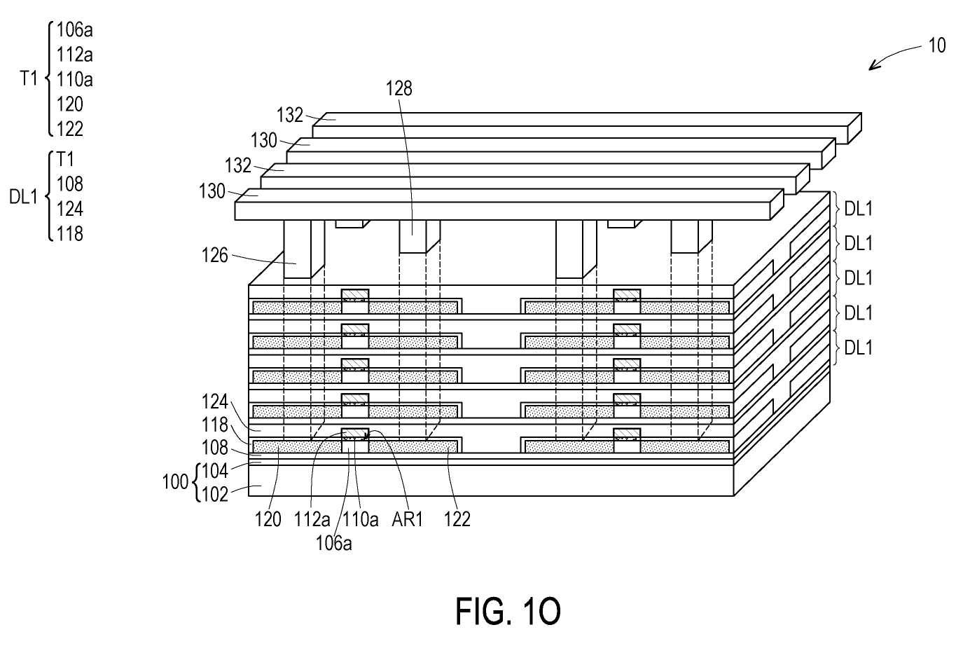

FIGS. 1A to FIG. 1O are figures of a manufacturing process of a semiconductor structure according to some embodiments of the invention. FIGS. 1A to FIG. 1C and FIG. 1L to FIG. 1O are perspective views. FIGS. 1D to FIG. 1K are cross-sectional views of the manufacturing process taken along section line I-I’ in FIG. 1C, wherein FIG. 1D is a cross-sectional view of FIG. 1C, and FIG. 1K is a cross-sectional view of FIG. 1L.

Referring to FIG. 1A, a substrate structure 100 is provided. The substrate structure 100 may include a device layer 102 and a dielectric layer 104. In some embodiments, the device layer 102 may be a peripheral circuit device layer. The dielectric layer 104 is located on the device layer 102. In some embodiments, the material of the dielectric layer 104 is, for example, oxide (e.g., silicon oxide).

In addition, an active material layer 106 may be provided. In some embodiments, the material of the active material layer 106 may be a semiconductor substrate such as a silicon substrate. In some embodiments, the active material layer 106 may have a first conductivity type (e.g., P-type). Hereinafter, the first conductivity type and the second conductivity type may be different conductivity types. In the present embodiment, the first conductivity type may be a P-type, and the second conductivity type may be a N-type, but the invention is not limited thereto. In other embodiments, the first conductivity type may be a N-type, and the second conductivity type may be a P-type. Furthermore, there may be a dielectric layer 108 on one side of the active material layer 106. In some embodiments, the material of the dielectric layer 108 is, for example, oxide (e.g., silicon oxide).

Referring to FIG. 1B, the dielectric layer 108 may be bonded to the dielectric layer 104. In some embodiments, the method of bonding the dielectric layer 108 and the dielectric layer 104 is, for example, a fusion bonding method. In some embodiments, after the dielectric layer 108 is bonded to the dielectric layer 104, a thinning process may be performed on the active material layer 106.

Referring to FIGS. 1C and FIG. 1D, the active material layer 106 may be patterned to form an active layer 106a. In some embodiments, the number of the active layers 106a may be plural, but the invention is not limited thereto. As long as the number of the active layers 106a is at least one, it falls within the scope of the invention.

Referring to FIG. 1E, a gate dielectric material layer 110 may be formed on the active layer 106a. In some embodiments, the material of the gate dielectric material layer 110 is, for example, a negative capacitance material. In some embodiments, the negative capacitance material is, for example, hafnium dioxide (HfO₂), zirconium dioxide (ZrO₂), aluminum oxide (Al₂O₃), yttrium aluminum garnet (YAG), aluminum nitride (AlN), hafnium aluminum oxide (HfAlO), hafnium silicate (HfSiO), or hafnium zirconium oxide (HfZrO). In some embodiments, the method of forming the gate dielectric material layer 110 is, for example, a chemical vapor deposition (CVD) method.

Referring to FIG. 1F, a gate material layer 112 may be formed on the gate dielectric material layer 110. In some embodiments, the material of the gate material layer 112 is, for example, doped polysilicon. In some embodiments, the method of forming the gate material layer 112 is, for example, a CVD method.

Referring to FIG. 1G, the gate material layer 112 may be patterned to form a gate 112a. In some embodiments, the gate material layer 112 may be patterned by a lithography process and an etching process to form the gate 112a.

Referring to FIG. 1H, a patterned photoresist layer 114 may be formed. The patterned photoresist layer 114 may expose the gate dielectric material layer 110 on one side of the gate 112a. In some embodiments, the patterned photoresist layer 114 may be formed by a lithography process.

A portion of the gate dielectric material layer 110 may be remove by using the patterned photoresist layer 114 as a mask to form an air gap AR1 under the gate 112a. In some embodiments, the method of removing the portion of the gate dielectric material layer 110 is, for example, a wet etching method.

Referring to FIG. 1I, the patterned photoresist layer 114 may be removed. In some embodiments, the method of removing the patterned photoresist layer 114 is, for example, a dry stripping method or a wet stripping method.

A patterned photoresist layer 116 may be formed. The patterned photoresist layer 116 may expose the gate dielectric material layer 110 located on another side of the gate 112a. In some embodiments, the patterned photoresist layer 116 may be formed by a lithography process.

Another portion of the gate dielectric material layer 110 may be remove by using the patterned photoresist layer 116 as a mask to form a gate dielectric layer 110a. In some embodiments, the method of removing the another portion of the gate dielectric material layer 110 is, for example, a dry etching method.

Referring to FIG. 1J, the patterned photoresist layer 116 may be removed. In some embodiments, the method of removing the patterned photoresist layer 116 is, for example, a dry stripping method or a wet stripping method.

A dielectric layer 118 may be formed on the active layer 106a on two sides of the gate 112a. In some embodiments, the material of the dielectric layer 118 is, for example, oxide (e.g., silicon oxide). In some embodiments, the method of forming the dielectric layer 118 is, for example, a CVD method.

Referring to FIGS. 1K and FIG. 1L, a doped region 120 and a doped region 122 may be formed in the active layer 106a on two sides of the gate 112a. In some embodiments, the doped region 120 may be used as a source region, and the doped region 122 may be used as a drain region, but the invention is not limited thereto. In some other embodiments, the doped region 120 may be used as a drain region, and the doped region 122 may be used as a source region. In addition, the doped region 120 and the doped region 122 may have a second conductivity type (e.g., N-type). In some embodiments, the method of forming the doped region 120 and the doped region 122 is, for example, an ion implantation method.

By the above method, a semiconductor device T1 may be formed. In some embodiments, the semiconductor device T1 may include the active layer 106a, the gate 112a, the gate dielectric layer 110a, the doped region 120, and the doped region 122.

Referring to FIG. 1M, a dielectric layer 124 may be formed on another side of the active material layer 106. Therefore, the dielectric layer 108 and the dielectric layer 124 may be formed on opposite sides of the active layer 106a. In some embodiments, the material of the dielectric layer 124 is, for example, oxide (e.g., silicon oxide). In some embodiments, the method of forming the dielectric layer 124 is, for example, a CVD method. In some embodiments, after the dielectric layer 124 is formed, a planarization process (e.g., chemical mechanical polishing (CMP) process) may be performed on the dielectric layer 124.

By the above method, a device layer DL1 may be formed on the substrate structure 100. In some embodiments, the device layer DL1 may include the semiconductor device T1, the dielectric layer 108, dielectric layer 124, and dielectric layer 118.

Referring to FIG. 1N, the step of bonding the dielectric layer 108 on another active material layer 106 to the dielectric layer 124 of the device layer DL1 and the steps of FIGS. 1C to FIG.1M may be repeated to form device layers DL1 on the substrate structure 100. The device layers DL1 are stacked on the substrate structure 100. In some embodiments, the method of bonding the dielectric layer 108 on another active material layer 106 to the dielectric layer 124 of the device layer DL1 is, for example, a fusion bonding method.

Referring to FIG. 1O, a conductive pillar 126 may be formed in the device layers DL1. The conductive pillar 126 may be electrically connected to the doped regions 120. In addition, a conductive pillar 128 may be formed in the device layers DL1. The conductive pillar 128 may be electrically connected to the doped regions 122. In some embodiments, the material of the conductive pillar 126 and the material of the conductive pillar 128 are, for example, tungsten or copper. In some embodiments, the conductive pillar 126 and the conductive pillar 128 may be formed by an interconnect process.

A conductive line 130 may be formed on the conductive pillar 126. The conductive line 130 may be electrically connected to the conductive pillar 126. A conductive line 132 may be formed on the conductive pillar 128. The conductive line 132 may be electrically connected to the conductive pillar 128. In some embodiments, the conductive line 130 may be used as a source line, and the conductive line 132 may be used as a bit line, but the invention is not limited thereto. In other embodiments, the conductive line 130 may be used as a bit line, and the conductive line 132 may be used as a source line. In some embodiments, the material of the conductive line 130 and the material of the conductive line 132 are, for example, aluminum or copper. In some embodiments, the conductive line 130 and the conductive line 132 may be formed by an interconnect process.

In addition, although not shown in the figure, the required dielectric layer may be formed on the device layers DL1, and the conductive pillar 126, the conductive pillar 128, the conductive line 130, and the conductive line 132 may be located in the dielectric layer, and the description thereof is omitted here.

Hereinafter, the semiconductor structure 10 of the above embodiments is described with reference to FIGS. 1K, FIG. 1L, and FIG. 1O. In addition, although the method for forming the semiconductor structure 10 is described by taking the above method as an example, the invention is not limited thereto.

Referring to FIGS. 1K, FIG. 1L, and FIG. 1O, a semiconductor structure 10 includes a substrate structure 100 and device layers DL1. In some embodiments, the substrate structure 100 may include a device layer 102 and a dielectric layer 104. The dielectric layer 104 is located on the device layer 102. The device layers DL1 are stacked on the substrate structure 100. The device layers DL1 include semiconductor devices T1. In some embodiments, each of the device layers DL1 includes the semiconductor devices T1. The semiconductor devices T1 in each of the device layers DL1 may be arranged in a direction parallel to the top surface of the substrate structure 100. In some embodiments, the semiconductor device T1 may be a Fin Field-Effect Transistor (FinFET). Each of the semiconductor devices T1 includes an active layer 106a, a gate 112a, a gate dielectric layer 110a, a doped region 120, and a doped region 122. The gate 112a is located on the active layer 106a and may intersect the active layer 106a. The gate dielectric layer 110a is located between the gate 112a and the active layer 106a. In some embodiments, the material of the gate dielectric layer 110a is, for example, a negative capacitance material. In some embodiments, the negative capacitance material is, for example, hafnium dioxide, zirconium dioxide, aluminum oxide, yttrium aluminum garnet, aluminum nitride, hafnium aluminum oxide, hafnium silicate, or hafnium zirconium oxide. There is an air gap AR1 on one side of the gate dielectric layer 110a. The air gap AR1 is located between the gate 112a and the active layer 106a. The doped region 120 and the doped region 122 are located in the active layer 106a on two sides of the gate 112a.

In some embodiments, each of the device layer DL1 may further include a dielectric layer 108 and a dielectric layer 124. The dielectric layer 108 and the dielectric layer 124 are located on opposite sides of the active layer 106a. In some embodiments, the dielectric layer 108 of one of the two adjacent device layers DL1 may be bonded to the dielectric layer 124 of the other of the two adjacent device layers DL1. In some embodiments, the dielectric layer 108 of the device layer DL1 closest to the substrate structure 100 may be bonded to the substrate structure 100. In some embodiments, the dielectric layer 108 of the device layer DL1 closest to the substrate structure 100 may be bonded to the dielectric layer 104. In some embodiments, each of the device layers DL1 may further include a dielectric layer 118. The dielectric layer 118 is located between the dielectric layer 124 and the doped region 120 and between the dielectric layer 124 and the doped region 122. The dielectric layer 118 may be further located on two sides of the doped region 120 and the doped region 122. In some embodiments, the dielectric layer 118 may seal the air gap AR1. In some embodiments, in a single device layer DL1, the dielectric layer 124 may fill the space between two adjacent semiconductor devices T1.

In some embodiments, the semiconductor structure 10 may further include a conductive pillar 126 and a conductive pillar 128. The conductive pillar 126 is located in the device layers DL1. The conductive pillar 126 may be electrically connected to the doped region 120. The conductive pillar 128 is located in the device layers DL1. The conductive pillar 128 may be electrically connected to the doped region 122. In some embodiments, the semiconductor structure 10 may further include a conductive line 130 and a conductive line 132. The conductive line 130 is located on the conductive pillar 126. The conductive line 130 may be electrically connected to the conductive pillar 126. The conductive line 132 is located on the conductive pillar 128. The conductive line 132 may be electrically connected to the conductive pillar 128.

In addition, the details (e.g., the material and the forming method) of the components in the semiconductor structure 10 have been described in detail in the above embodiments, and the description thereof is not repeated here.

Based on the above embodiments, in the semiconductor structure 10 and the manufacturing method thereof, since the device layers DL1 are stacked on the substrate structure 100, the device density of the semiconductor device T1 can be effectively improved. In addition, when the semiconductor device T1 is a 1T-DRAM device, since there is the air gap AR1 on one side of the gate dielectric layer 110a, and the air gap AR1 is located between the gate 112a and the active layer 106a, the memory judgment window of the memory device can be improved.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate structure; and
first device layers stacked on the substrate structure, wherein the first device layers comprise semiconductor devices, wherein each of the semiconductor devices comprises:
an active layer;
a gate located on the active layer;
a gate dielectric layer located between the gate and the active layer, wherein there is an air gap on one side of the gate dielectric layer, and the air gap is located between the gate and the active layer;
a first doped region and a second doped region located in the active layer on two sides of the gate;
a first dielectric layer and a second dielectric layer located on opposite sides of the active layer; and
a third dielectric layer located between the second dielectric layer and the first doped region and between the second dielectric layer and the second doped region, wherein the third dielectric layer seals the air gap.

2. The semiconductor structure according to claim 1, wherein a material of the gate dielectric layer comprises a negative capacitance material.

3. The semiconductor structure according to claim 2, wherein the negative capacitance material comprises hafnium dioxide, zirconium dioxide, aluminum oxide, yttrium aluminum garnet, aluminum nitride, hafnium aluminum oxide, hafnium silicate, or hafnium zirconium oxide.

4. The semiconductor structure according to claim 1, wherein the first dielectric layer of one of two adjacent first device layers is bonded to the second dielectric layer of the other of the two adjacent first device layers.

5. The semiconductor structure according to claim 1, wherein the first dielectric layer of the first device layer closest to the substrate structure is bonded to the substrate structure.

6. The semiconductor structure according to claim 1, wherein in single one of the first device layers, the second dielectric layer fills a space between two adjacent semiconductor devices.

7. The semiconductor structure according to claim 1, wherein the third dielectric layer is further located on two sides of the first doped region and the second doped region.

8. The semiconductor structure according to claim 1, wherein the substrate structure comprises:
a second device layer; and
a third dielectric layer located on the second device layer, wherein
the first dielectric layer of the first device layer closest to the substrate structure is bonded to the third dielectric layer.

9. The semiconductor structure according to claim 1, further comprising:
a first conductive pillar located in the first device layers and electrically connected to the first doped region; and
a second conductive pillar located in the first device layers and electrically connected to the second doped region.

10. The semiconductor structure according to claim 9, further comprising:
a first conductive line located on the first conductive pillar and electrically connected to the first conductive pillar; and
a second conductive line located on the second conductive pillar and electrically connected to the second conductive pillar.

11. The semiconductor structure according to claim 1, wherein each of the first device layers comprises the semiconductor devices, and the semiconductor devices in each of the first device layers are arranged in a direction parallel to a top surface of the substrate structure.

12. A manufacturing method of a semiconductor structure, comprising:
providing a substrate structure; and
forming first device layers on the substrate structure, wherein the first device layers are stacked on the substrate structure, the first device layers comprise semiconductor devices, and each of the semiconductor devices comprises:
an active layer;
a gate located on the active layer;
a gate dielectric layer located between the gate and the active layer, wherein there is an air gap on one side of the gate dielectric layer, and the air gap is located between the gate and the active layer;
a first doped region and a second doped region located in the active layer on two sides of the gate;
a first dielectric layer and a second dielectric layer located on opposite sides of the active layer; and
a third dielectric layer located between the second dielectric layer and the first doped region and between the second dielectric layer and the second doped region, wherein the third dielectric layer seals the air gap.

13. The manufacturing method of the semiconductor structure according to claim 12, wherein a method of forming each of the semiconductor devices comprises:
forming a gate dielectric material layer on the active layer;
forming a gate material layer on the gate dielectric material layer;
patterning the gate material layer to form the gate;
forming a first patterned photoresist layer, wherein the first patterned photoresist layer exposes the gate dielectric material layer located on one side of the gate;
removing a portion of the gate dielectric material layer by using the first patterned photoresist layer as a mask to form the air gap under the gate;
removing the first patterned photoresist layer;
forming a second patterned photoresist layer, wherein the second patterned photoresist layer exposes the gate dielectric material layer located on another side of the gate;
removing another portion of the gate dielectric material layer by using the second patterned photoresist layer as a mask to form the gate dielectric layer; and
removing the second patterned photoresist layer.

14. The manufacturing method of the semiconductor structure according to claim 13, wherein the method of forming each of the semiconductor devices further comprises:
forming the first doped region and the second doped region in the active layer on the two sides of the gate.

15. The manufacturing method of the semiconductor structure according to claim 13, wherein a method of removing the portion of the gate dielectric material layer comprises a wet etching method, and a method of removing the another portion of the gate dielectric material layer comprises a dry etching method.

16. The manufacturing method of the semiconductor structure according to claim 12, further comprising:
before forming the first doped region and the second doped region, forming a dielectric layer on the active layer on the two sides of the gate.

17. The manufacturing method of the semiconductor structure according to claim 12, wherein a method of forming the active layer comprises:
providing an active material layer; and
patterning the active material layer to form the active layer.
